(19) United States
(12) Patent Application Publication
(10) Pub. No.: US 2012/0313096 A1
(43) Pub. Date: Dec. 13, 2012

(54) OXIDE SEMICONDUCTOR COMPOSITION AND PREPARATION METHOD THEREOF, METHOD OF FORMING OXIDE SEMICONDUCTOR THIN FILM, METHOD OF FABRICATING ELECTRONIC DEVICE AND ELECTRONIC DEVICE FABRICATED THEREBY

(75) Inventors: Hyun Jae KIM, Seoul (KR); You Seung Rim, Seoul (KR); Hyun Soo Lim, Seoul (KR); Dong Lim Kim, Seoul (KR)

(73) Assignee: Industry-Academics Cooperation Foundation, Yonsei University, Seoul (KR)

(21) Appl. No.: 13/343,013

(22) Filed: Jan. 4, 2012

(30) Foreign Application Priority Data
Jun. 9, 2011 (KR) 10-2011-0055770

(51) Int. Cl. H01L 29/786; G03F 7/027; G03F 7/004; H01L 21/20; H01L 29/04

(52) U.S. Cl. 257/57; 438/483; 257/52; 430/270.1; 430/281.1; 257/E21.09; 257/E29.273; 257/E29.003

(57) ABSTRACT

Provided are an oxide semiconductor composition, a preparation method thereof, an oxide semiconductor thin film using the composition, and a method of forming an electronic device. The oxide semiconductor composition includes a photosensitive material and an oxide semiconductor precursor.

### CROSS-REFERENCE TO RELATED APPLICATIONS

This U.S. non-provisional patent application claims priority under 35 U.S.C. §119 of Korean Patent Applications Nos. 10-2011-0055770, filed on Jun. 9, 2011, the entire contents of which are hereby incorporated by reference.

### BACKGROUND

The exemplary embodiments of the invention concepts disclosed herein relates to a method of forming a solution-based oxide thin film, and more particularly, to a composition for a solution-based oxide thin film, a method of preparing the composition, a method of forming an oxide thin film, and an electronic device fabricated thereby.

Recently, much research has been widely conducted on oxide semiconductors which will replace silicon-based semiconductor devices. In terms of a material, results of the research on single, binary, and tertiary compounds based on indium oxide (In₂O₃), zinc oxide (ZnO), and gallium oxide (Ga₂O₃) have been reported. Meanwhile, in terms of manufacturing process, much research has been conducted on a solution-based process replacing typical vacuum deposition.

Although oxide semiconductors have an amorphous phase like hydrogenated amorphous silica, the oxide semiconductors are suitable to a high image quality liquid crystal display (LCD) and an active matrix organic light-emitting diode (AMOLED) because of very excellent mobility characteristics. Also, a technology of fabricating the oxide semiconductors using a solution-based process may be low cost in comparison to a high-cost vacuum deposition method.

Generally in a process of fabricating an electronic device, a thin film is formed, and then is patterned into a desired shape by using a photolithography. A typical photolithography process includes a series of steps in which a photosensitive material such as a photoresist is coated on a target thin film, a photoresist pattern is then formed by performing light exposure and development, and the target thin film is etched by using the photoresist pattern as a mask to form a desired pattern. The photoresist material exposed by light is photochemically changed, and thus, portions exposed and unexposed by light have chemically different structures. Therefore, any one portion is selectively removed by means of an appropriate developing solution and a portion that is not removed by the developing solution will be the photoresist pattern.

The photoresist pattern used in the etching of the target film has to be removed through a process such as ashing, stripping, etc. The ashing is a process of removing the photoresist pattern using oxygen plasma in a plasma etching apparatus, and the stripping is a process of removing the photoresist pattern at about 125° C. by using a mixture solution of sulfuric acid and oxidant. With respect to the removal of the photoresist pattern, it is necessary to remove the photoresist pattern as fast as possible without affecting properties of patterns formed thereunder.

However, properties of an oxide thin film used as an active or channel layer may deteriorate due to the environments such as a high-temperature oxidation process, plasma particle energy and reactive radicals of a photolithography process, and a chemical solution in a stripping process.

Also, the photolithography process makes a process complicated as well as increase in overall cost of fabricating a device.

### SUMMARY

The exemplary embodiments of the inventive concepts provide a composition for an oxide semiconductor thin film.

The exemplary embodiments of the inventive concepts also provide a method of preparing the composition for an oxide semiconductor thin film.

The exemplary embodiments of the inventive concepts also provide a method of forming the oxide semiconductor thin film.

The exemplary embodiments of the inventive concepts also provide a method of forming an electronic device including the oxide semiconductor thin film.

The exemplary embodiments of the inventive concepts also provide an electronic device including the oxide semiconductor thin film.

The exemplary embodiments of the inventive concepts also provide a method of forming a low-temperature processable oxide semiconductor thin film, a composition for the same, and an oxide semiconductor device fabricated by a low-temperature process.

Embodiments of inventive concepts provide an oxide semiconductor composition comprising: a photosensitive material; and an oxide semiconductor precursor.

In some embodiments, the photosensitive material may be included in a range of about 0.1 mol to about 1 mol with respect to 1 mol of the oxide semiconductor precursor.

In other embodiments, light absorption of the photosensitive material may be generated in an ultraviolet wavelength region of about 200 nm to about 450 nm.

In still other embodiments, the photosensitive material may be selected from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

In even other embodiments, the oxide semiconductor precursor may include a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.

In yet other embodiments, the oxide semiconductor precursor may include an indium compound, a zinc compound, and a gallium compound.

In further embodiments, a molar ratio of zinc compound to indium compound is in a range of about 1:0.1 to about 0.1:1 and a molar ratio of zinc compound to gallium compound may be in a range of about 1:0.1 to about 1:1.

In still further embodiments of the inventive concepts, a method of forming an oxide semiconductor thin film comprising: coating an oxide semiconductor composition including a photosensitive material and an oxide semiconductor precursor on a substrate to form an oxide semiconductor thin film; patterning the oxide semiconductor thin film; and heat treating the substrate in a temperature range of about 100° C.˜350° C.

In even further embodiments, the patterning of the oxide semiconductor thin film may comprise: irradiating light to the oxide semiconductor thin film; and removing the oxide semiconductor thin film that is not irradiated with light.

In yet further embodiments, the preparing of the photosensitive material may comprise selecting the photosensitive material from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

In much further embodiments, the removing of the oxide semiconductor thin film that is not irradiated with light may comprise providing ethanol, methanol, isopropyl alcohol, propanol, 2-methoxyethanol, acetonitrile, acetone, butanol, distilled water, or a combination thereof as an etching solution to the oxide semiconductor thin film that is not irradiated with light.

In still much further embodiments, during the heat treating, the photosensitive material may be evaporated and removed and the oxide semiconductor precursor may be removed, thereby form the oxide semiconductor thin film patterns.

In even much further embodiments, the etching solution may be provided by an spraying method, an ultrasonic cleaning method, a dipping method, or a bubble method.

In yet much further embodiments, the coating of the oxide semiconductor composition on the substrate may comprise coating the oxide semiconductor composition on a flexible substrate, a glass substrate, or a silicon substrate.

In some embodiments, the heat treating may be performed with a furnace, a hot plate, or a rapid thermal process.

In other embodiments, the method may comprise performing a heat treatment to remove a solvent, before the removing of the oxide semiconductor thin film that is not irradiated with light.

In still other embodiments of the inventive concepts, an electronic device may comprise: an oxide semiconductor thin film formed by the foregoing method of forming the oxide semiconductor thin film; a gate electrode spaced apart from and overlapping the oxide semiconductor thin film; and source and drain electrodes electrically connected to the oxide semiconductor thin film and positioned at both sides of the gate electrode.

In even other embodiments of the inventive concepts, a semiconductor device may comprise an oxide semiconductor thin film on a flexible substrate or a glass substrate. The oxide semiconductor thin film is formed by the foregoing method of forming the oxide semiconductor thin film.

In yet other embodiments of the inventive concepts, a method of preparing an oxide semiconductor composition may comprise: preparing an oxide semiconductor precursor solution; preparing a photosensitive material solution; and mixing the oxide semiconductor precursor solution and the photosensitive material solution.

In further embodiments, the preparing of the oxide semiconductor precursor solution may comprise mixing a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, a strontium compound.

In still further embodiments, the preparing of the photosensitive material solution may include selecting the photosensitive material from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

In even further embodiments of the inventive concepts, an oxide thin film composition may comprise an oxide thin film precursor and a photosensitive material having a boiling point of about 400° C. or less and light absorption generated in an ultraviolet wavelength region of about 200 nm to about 450 nm.

In yet further embodiments, the photosensitive material may be selected from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

In much further embodiments, the oxide thin film precursor may include a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.

### BRIEF DESCRIPTION OF THE DRAWINGS

The accompanying drawings are included to provide a further understanding of the exemplary embodiments of the inventive concepts, and are incorporated in and constitute a part of this specification. The drawings illustrate exemplary embodiments of the inventive concepts and, together with the description, serve to explain principles of the inventive concepts. In the drawings:

FIG. 1 illustrates preparation of an oxide semiconductor composition according to an embodiment of the inventive concepts;

FIG. 2 illustrates a method of forming an oxide semiconductor thin film according to an embodiment of the inventive concepts;

FIGS. 3 through 8 illustrate fabrication of a bottom gate thin film transistor in which a channel layer is formed on a gate according to an example of the inventive concepts;

FIG. 9 is a graph showing electrical property changes of indium-gallium-zinc oxide-based thin film transistor using the composition according to an embodiment of the inventive concepts, an unpatterned thin film transistor and a thin film transistor using a typical photolithography process (use a photoresist);

FIGS. 10 through 12 are graphs showing transfer characteristics with respect to positive bias stress (PBS) tests of thin film transistors according to each process;

FIG. 13 shows threshold voltage values measured according to each condition in which about 20 V of a gate bias voltage and about 10.1 V of a drain voltage are continuously applied for about 1 second, 10 seconds, 100 seconds, and 1000 seconds as a PBS test condition;

FIGS. 14 through 16 are graphs showing transfer characteristics with respect to negative bias stress (NBS) tests of thin film transistors according to each process; and

FIG. 17 shows threshold voltage values measured according to each condition in which about −20 V of a gate bias voltage and about 10.1 V of a drain voltage are continuously applied for about 1 second, 10 seconds, 100 seconds, and 1000 seconds as a NBS test condition.

### DETAILED DESCRIPTION OF THE EMBODIMENTS

Advantages and features of the inventive concepts, and implementation methods thereof will be clarified through following embodiments described with reference to the accompanying drawings. The exemplary embodiments of the inventive concepts may, however, be embodied in different forms and should not be construed as limited to the embodiments set forth herein. Rather, these embodiments are provided so that this disclosure will be thorough and complete, and will fully convey the scope of the inventive concepts to those skilled in the art.

Though not defined, all terms (including technical or scientific terms) used herein have the same meanings as those generally accepted by universal technologies in the related art to which the present invention pertains. The terms defined by general dictionaries may be construed as having the same meanings as those in the related art and/or the text of the present application, and will not be construed as being conceptualized or excessively formal although the terms are not clearly defined expressions herein.

In the following description, the technical terms are used only for explaining a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Oxide Semiconductor Composition

Some embodiments of the inventive concepts relate to a composition for an oxide thin film and a preparation method thereof, a method of forming an oxide thin film using the composition, a method of forming a semiconductor device, an electronic device fabricated through the method, an oxide semiconductor device, etc. According to an embodiment of the inventive concepts, an oxide semiconductor composition may be provided. The oxide semiconductor composition may be used as a material for a channel layer of a thin film transistor, a resistor, a capacitor, an inductor, and/or a diode, and may be applied to a display such as LCD or AMOLED or a solar cell.

The oxide semiconductor composition according to an embodiment of the inventive concepts includes a precursor solution for an oxide semiconductor and a photosensitive material. The precursor solution provides thin film constituting elements. For example, the precursor solution may include an indium compound, a gallium compound, and a zinc compound when a finally formed thin film is an indium gallium zinc oxide (IGZO) thin film including indium, gallium, and zinc.

In order to improve thin film properties, one or more additives may be included among various additives, e.g., a dispersant, a binding agent, a compatibilizing agent, a stabilizer, a pH adjuster, a viscosity modifier, a carrier control agent, an antifoaming agent, a detergent, a curing agent, etc.

The oxide semiconductor precursor solution according to an embodiment of the inventive concepts may include a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.

The zinc compound may be selected from zinc salts and hydrates thereof, but the zinc compound is not limited thereto. Specific examples of the zinc compound may include zinc citrate dihydrate, zinc acetate, zinc acetate dihydrate, zinc acetylacetonate hydrate, zinc acrylate, zinc chloride, zinc diethyldithiocarbamate, zinc dimethyldithiocarbamate, zinc fluoride, zinc fluoride hydrate, zinc hexafluoroacetylacetonate dihydrate, zinc methacrylate, zinc nitrate hexahydrate, zinc nitrate hydrate, zinc trifluoromethanesulfonate, zinc undecylenate, zinc trifluoroacetate hydrate, zinc tetrafluoroborate hydrate, zinc perchlorate hexahydrate, and hydrates thereof, and the zinc compound may include one or more selected therefrom.

The indium compound may be selected from indium salts and hydrates thereof, but the indium compound is not limited thereto. Specific examples of the indium compound may include indium chloride, indium chloride tetrahydrate, indium fluoride, indium fluoride trihydrate, indium hydroxide, indium nitrate hydrate, indium acetate hydrate, indium acetylacetonate, indium acetate or combinations thereof.

The tin compound may be selected from tin salts and hydrates thereof, but the tin compound is not limited thereto. Specific examples of the tin compound may include tin(II) chloride, tin(II) iodide, tin(II) chloride dihydrate, tin(II) bromide, tin(II) fluoride, tin(II) oxalate, tin(II) sulfide, tin(II) acetate, tin(IV) chloride, tin(IV) chloride pentahydrate, tin(IV) fluoride, tin(IV) iodide, tin(IV) sulfide, tin(IV) tert-butoxide, and hydrates thereof, and the tin compound may include one or more selected therefrom.

The gallium compound may be selected from gallium salts and hydrates thereof, but the gallium compound is not limited thereto. Specific examples of the gallium compound may include gallium nitride, gallium phosphide, gallium(II) chloride, gallium(III) acetylacetonate, gallium(III) bromide, gallium(III) chloride, gallium(III) fluoride, gallium(III) iodide, gallium(III) nitrate hydrate, gallium(III) sulfate, gallium(III) sulfate hydrate, and hydrates thereof, and the gallium compound may include one or more selected therefrom.

The zirconium compound may be selected from zirconium salts and hydrates thereof, but the zirconium compound is not limited thereto. Specific examples of the zirconium compound may include zirconium acetate, zirconium nitrate, zirconium(II) hydride, zirconium(IV) acetate hydroxide, zirconium(IV) acetylacetonate, zirconium(IV) butoxide solution, zirconium(IV) carbide, zirconium(IV) chloride, zirconium(IV) ethoxide, zirconium(IV) fluoride, zirconium(IV) fluoride hydrate, zirconium(IV) hydroxide, zirconium(IV) iodide, zirconium(IV) sulfate hydrate, zirconium(IV) tert-butoxide, and hydrates thereof, and the zirconium compound may include one or more selected therefrom.

The aluminum compound may be selected from aluminum salts and hydrates thereof, but the aluminum compound is not limited thereto. Specific examples of the aluminum compound may include aluminum acetate, aluminum acetylacetonate, aluminum borate, aluminum bromide, aluminum carbide, aluminum chloride, aluminum chloride hexahydrate, aluminum chloride hydrate, aluminum ethoxide, aluminum fluoride, aluminum hydroxide hydrate, aluminum iodide, aluminum isopropoxide, aluminum nitrate nonahydrate, aluminum nitride, aluminum phosphate, aluminum sulfate, aluminum sulfate hexadecahydrate, aluminum sulfate hydrate, aluminum tert-butoxide, and hydrates thereof, and the aluminum compound may include one or more selected therefrom.

The neodymium compound may be selected from neodymium salts and hydrates thereof, but the neodymium compound is not limited thereto. Specific examples of the neodymium compound may include neodymium(II) iodide, neodymium(III) acetate hydrate, neodymium(III) acetylacetonate hydrate, neodymium(III) bromide, neodymium(III) bromide hydrate, neodymium(III) carbonate hydrate, neodymium(III) chloride, neodymium(III) chloride hexahydrate, neodymium(III) fluoride, neodymium(III) hydroxide hydrate, neodymium(III) iodide, neodymium(III) isopropoxide, neodymium(III) nitrate hexahydrate, neodymium(III) nitrate hydrate, neodymium(III) oxalate hydrate, neodymium(III) phosphate hydrate, neodymium(III) sulfate, neodymium(III) sulfate hydrate, and hydrates thereof, and the neodymium compound may include one or more selected therefrom.

The scandium compound may be selected from scandium salts and hydrates thereof, but the scandium compound is not limited thereto. Specific examples of the scandium compound may include scandium acetate hydrate, scandium acetylacetonate hydrate, scandium chloride, scandium chloride hexahydrate, scandium chloride hydrate, scandium fluoride, scandium nitrate hydrate, and hydrates thereof, and the scandium compound may include one or more selected therefrom.

The tantalum compound may be selected from tantalum salts and hydrates thereof, but the tantalum compound is not limited thereto. Specific examples of the tantalum compound may include tantalum bromide, tantalum chloride, tantalum fluoride, and hydrates thereof, and the tantalum compound may include one or more selected therefrom.

The titanium compound may be selected from titanium salts and hydrates thereof, but the titanium compound is not limited thereto. Specific examples of the titanium compound may include titanium bromide, titanium chloride, titanium fluoride, and hydrates thereof, and the titanium compound may include one or more selected therefrom.

The barium compound may be selected from barium salts and hydrates thereof, but the barium compound is not limited thereto. Specific examples of the barium compound may include barium acetate, barium acetylacetonate, barium bromide, barium chloride, barium fluoride, barium hexafluoacetylacetonate, barium hydroxide, barium nitrate, and hydrates thereof, and the barium compound may include one or more selected therefrom.

The lanthanum compound may be selected from lanthanum salts and hydrates thereof, but the lanthanum compound is not limited thereto. Specific examples of the lanthanum compound may include lanthanum acetate, lanthanum acetylacetonate, lanthanum bromide, lanthanum chloride, lanthanum hydroxide, lanthanum fluoride, lanthanum nitrate, and hydrates thereof, and the lanthanum compound may include one or more selected therefrom.

The manganese compound may be selected from manganese salts and hydrates thereof, but the manganese compound is not limited thereto. Specific examples of the manganese compound may include manganese acetate, manganese acetylacetonate, manganese bromide, manganese chloride, manganese fluoride, manganese nitrate, and hydrates thereof, and the manganese compound may include one or more selected therefrom.

The chromium compound may be selected from chromium salts and hydrates thereof, but the chromium compound is not limited thereto. Specific examples of the chromium compound may include chromium acetate, chromium acetylacetonate, chromium bromide, chromium chloride, chromium fluoride, chromium nitrate, and hydrates thereof, and the chromium compound may include one or more selected therefrom.

The strontium compound may be selected from strontium salts and hydrates thereof, but the strontium compound is not limited thereto. Specific examples of the strontium compound may include strontium acetate, strontium acetylacetonate, strontium bromide, strontium chloride, strontium fluoride, strontium hydroxide, strontium nitrate, and hydrates thereof, and the strontium compound may include one or more selected therefrom,

The yttrium compound may be selected from yttrium salts and hydrates thereof, but the yttrium compound is not limited thereto. Specific examples of the yttrium compound may include yttrium acetate, yttrium acetylacetonate, yttrium chloride, yttrium fluoride, yttrium nitrate, and hydrates thereof, and the yttrium compound may include one or more selected therefrom.

The cerium compound may be selected from cerium salts and hydrates thereof, but the cerium compound is not limited thereto. Specific examples of the cerium compound may include cerium(III) acetate hydrate, cerium(III) acetylacetonate hydrate, cerium(III) bromide, cerium(III) carbonate hydrate, cerium(III) chloride, cerium(III) chloride heptahydrate, cerium(III) fluoride, cerium(III) iodide, cerium(III) nitrate hexahydrate, cerium(III) oxalate hydrate, cerium(III) sulfate, cerium(III) sulfate hydrate, cerium(III) sulfate octahydrate, cerium(IV) fluoride, cerium(IV) hydroxide, cerium(IV) sulfate, cerium(IV) sulfate hydrate, cerium(IV) sulfate tetrahydrate, and hydrates thereof, and the cerium compound may include one or more selected therefrom.

The hafnium compound may be selected from hafnium salts and hydrates thereof, but the hafnium compound is not limited thereto. Specific examples of the hafnium compound may include hafnium chloride, hafnium fluoride or combinations thereof.

The silicon compound may include one or more selected from the group consisting of silicon tetraacetate, silicon tetrabromide, silicon tetrachloride, silicon tetrafluoride or combinations thereof.

In the oxide semiconductor precursor according to an embodiment of the inventive concepts, atomic number ratio of zinc to indium, tin, gallium, hafnium, magnesium, aluminum, yttrium, tantalum, titanium, zirconium, barium, lanthanum, manganese, tungsten, molybdenum, cerium, chromium, scandium, silicon, neodymium, and/or strontium may be in a range of about 1:0.01˜1:1.

Concentrations of each of the oxide semiconductor precursor constituting components according to an embodiment of the inventive concepts may be in a range of about 0.1 M˜10 M, respectively.

According to an embodiment of the inventive concepts, the oxide semiconductor precursor may include an indium compound, a zinc compound, and a gallium compound. In this case, a molar ratio of zinc compound to indium compound may be in a range of about 1:0.1˜0.1:1, and a molar ratio of zinc compound to gallium compound may be in a range of about 1:0.1˜1:1.

The photosensitive material included in the oxide semiconductor composition according to an embodiment of the inventive concepts forms a strong bond with the oxide semiconductor precursor in the composition by light irradiation, e.g., ultraviolet irradiation such that a leaching solution (etching solution) which will be described later may selectively remove only the oxide semiconductor precursor that is not irradiated with light. According to an embodiment of the inventive concepts, an oxide semiconductor thin film in a gel state will be formed when a solvent is removed from a coated oxide semiconductor composition. When the light irradiates the oxide semiconductor gel, the photosensitive material, for example, may form a chelating complex with the oxide semiconductor precursor in the composition. According to an embodiment of the inventive concepts, examples of the photosensitive material may be selected from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and combinations thereof. According to an embodiment of the inventive concepts, light absorption of the photosensitive material may be generated in an ultraviolet wavelength region of about 200 nm to about 450 nm. According to an embodiment of the inventive concepts, a boiling point of the photosensitive material may be about 350° C. or less. In this case, when a heat treatment process after the coating of the composition is performed, for example, at about 35° C., the photosensitive material may be removed by evaporation as well as the oxide semiconductor thin film is formed. Also, since the heat treatment may be performed at a low temperature of about 350° C., embodiments of the inventive concepts may be applied to a large-area glass substrate or a flexible. According to an embodiment of the inventive concepts, the photosensitive material may be included in a range of about 0.1˜1 mol with respect to 1 mol of the oxide semiconductor precursor.

The oxide semiconductor composition according to an embodiment of the inventive concepts may further include a solvent that may dissolve the foregoing compounds. For example, the solvent may include one or more selected from the group consisting of deionized water, methanol, ethanol, propanol, isopropanol, 2-methoxyethanol, 2-ethoxyethanol, 2-proxyethanol, 2-butoxyethanol, methyl cellosolve, ethyl cellosolve, diethylene glycol methyl ether, ethylene glycol ethyl ether, dipropylene glycol methyl ether, toluene, xylene, hexane, heptane, octane, ethyl acetate, butyl acetate, diethylene glycol dimethyl ether, diethylene glycol dimethyl ethyl ether, methyl methoxypropionic acid, ethyl ethoxypropionic acid, ethyl lactic acid, propylene glycol methyl ether acetate, propylene glycol methyl ether, propylene glycol propyl ether, methyl cellosolve acetate, ethyl cellosolve acetate, diethylene glycol methyl acetate, diethylene glycol ethyl acetate, acetone, methyl isobutyl ketone, cyclohexanone, dimethylformamide (DMF), N,N-dimethylacetamide (DMAc), N-methyl-2-pyrrolidone, γ-butyrolactone, diethyl ether, ethylene glycol dimethyl ether, diglaim, tetrahydrofuran, acetylacetone, and acetonitrile.

Leaching Solution (Etching Solution)

A leaching solution (etching solution) according to an embodiment of the inventive concepts may be ethanol, methanol, isopropyl alcohol, propanol, 2-methoxyethanol, acetonitrile, acetone, butanol, distilled water, or a combination thereof. The leaching solution or the etching solution according to an embodiment of the inventive concepts removes a light-unirradiated oxide semiconductor composition thin film (e.g., a gel state) and leaves a light-irradiated oxide semiconductor composition thin film (e.g., an oxide semiconductor composition gel) intact, or vice versa.

Preparation of Oxide Semiconductor Composition

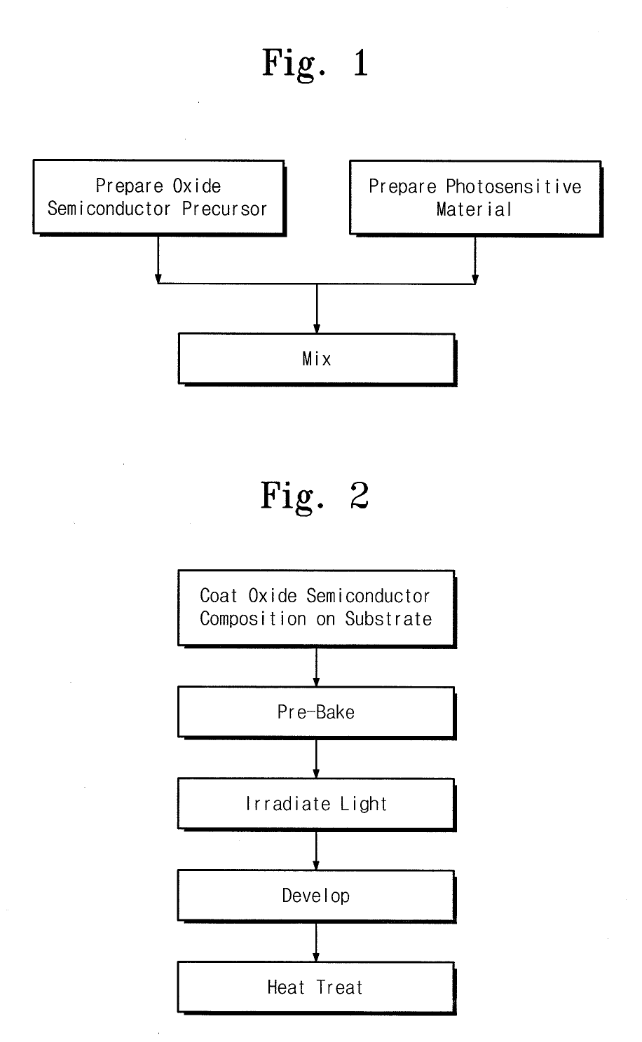

FIG. 1 illustrates preparation of an oxide semiconductor composition according to an embodiment of the inventive concepts. Referring to FIG. 1, an oxide semiconductor precursor and a photosensitive material are prepared. It does not matter which one is prepared first and/or both of them may be prepared at the same time.

Preparation of Oxide Semiconductor Precursor Solution

The oxide semiconductor precursor may include a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.

(InGaZnO(IGZO) Precursor Solution)

For example, the oxide semiconductor precursor may include a zinc compound, an indium compound, and a gallium compound. For this purpose, 2-methoxyethanol was prepared as a solvent, and indium nitrate hydrate, gallium nitrate hydrate, and zinc acetate dehydrate were prepared as oxide semiconductor constituting components. Monoethanolamine and acetic acid (CH₃COOH) were used as solution stabilizers.

In order to obtain a molar ratio (atomic number ratio) between indium, gallium and zinc of about 3:0.25:1 and a total molar concentration of about 0.2 M, each material were mixed together according to the molar ratio, and then the 2-methoxyethanol solvent was added. Thereafter, monoethanolamine and acetic acid (CH₃COOH) prepared for resulting sol stabilizing were added at an appropriate ratio. Next, the mixed solution was stirred at a rate of about 300 rpm for about 30 minutes by using a magnetic bar at a hot plate temperature of about 70° C. Aging for stabilization was performed on the sufficiently stirred solution for about 24 hours. The sufficiently stirred solution had a yellow transparent form, and impurities in the solution were filtered by using a 0.25 μm filter.

(InZnO(IZO) Precursor Solution)

2-methoxyethanol was prepared as a solvent, and indium nitrate hydrate and zinc acetate dehydrate were prepared as oxide semiconductor constituting components. In order to obtain a molar ratio (atomic number ratio) between indium and zinc of about 3:1 and a total molar concentration of about 0.2 M, each material is mixed according to the molar ratio, and then the 2-methoxyethanol solvent was added. Thereafter, monoethanolamine and acetic acid (CH₃COOH) as stabilizers for stabilization and conductivity adjustment of the oxide solution were added and stirred at a rate of about 340 rpm for about 40 minutes by using a magnetic bar at a hot plate temperature of about 70° C. Subsequently, aging for stabilization was performed for about 24 hours. The sufficiently stirred solution had a yellow transparent form, and impurities in the solution were filtered by using a 0.25 μm filter.

Photosensitive Material Preparation

The photosensitive material may be selected from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

Mixing of Oxide Semiconductor Precursor and Photosensitive Material

The prepared oxide semiconductor precursor solution and the selected photosensitive material were mixed. For example, 1 mol of the photosensitive material with respect to a total 1 mol of the oxide semiconductor precursor was mixed in a yellow room facility that may block ultraviolet rays. For example, 1 mol of benzoylacetone (C₁₀H₁₀O₂) with respect to the total 1 mol of indium, gallium, and zinc was added and stirred for about 30 minutes, and then an oxide semiconductor composition was prepared by putting the stirred solution in a brown bottle having a large ultraviolet-blocking effect.

Oxide Semiconductor Thin Film Formation

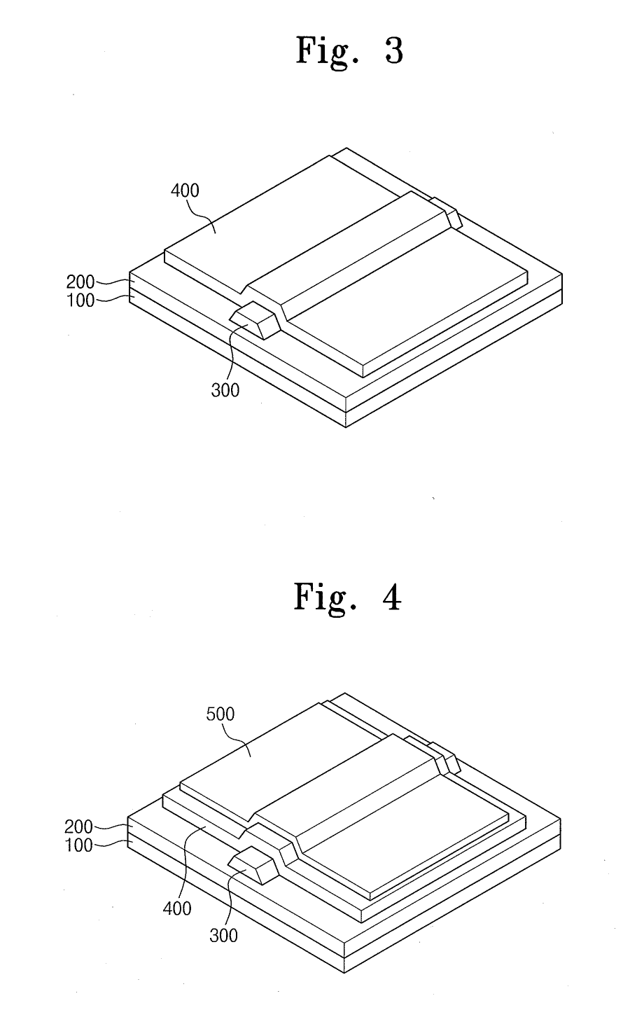

FIG. 2 illustrates a method of forming an oxide semiconductor thin film according to an embodiment of the inventive concepts. Referring to FIG. 2, an oxide semiconductor composition prepared with the method described previously is coated on a substrate. A semiconductor-based substrate, a glass substrate, or a flexible substrate may be used as the substrate. Examples of the semiconductor-based substrate may be a silicon substrate, a germanium substrate, a compound semiconductor substrate such as a silicon-germanium substrate, a sapphire substrate, etc. However, the semiconductor-based substrate is not limited thereto. For coating of the oxide semiconductor composition, spin coating, dip coating, ink jet printing, screen printing, a spray method, a roll-to-roll process may be used. For example, the oxide semiconductor composition is coated by using a spin coating method. The spin coating method may be performed in various steps, and for example, may be performed in 5 steps such as at 500 rpm for 10 seconds, at 1500 rpm for 10 seconds, at 3000 rpm for 30 seconds, at 1500 rpm for 10 seconds, and at 500 rpm for 5 seconds. After the oxide semiconductor composition is coated, and a solvent may be removed by performing pre-bake. As a result, an oxide semiconductor thin film in a gel state (oxide semiconductor gel) is formed. For example, the pre-bake may be performed at about 90° C. for about 2 minutes by using a hot plate. A furnace or a rapid thermal process may be used instead of the hot plate.

Next, light irradiation and leaching process are performed as a process of patterning the oxide semiconductor thin film. An appropriate apparatus may be used for the light irradiation, and for example, a light exposure may be performed for about 15 minutes by using an aligner (ultraviolet (UV) radiation 365 nm, output 350 W, 25 mW/cm²) capable of irradiating ultraviolet having a 365 nm wavelength. At this time, a shadow mask, in which a portion where a pattern has to remain is opened, may be used. In a light-irradiated portion, a photosensitive material may form a strong bond with an oxide semiconductor precursor in the composition, for example, a chelating complex. Thus, when an appropriate leaching solution is used, a light-unirradiated portion is selectively removed and the light-irradiated portion may remain intact.

Next, a leaching process is performed to form an oxide semiconductor thin film having desired patterns by removing the light-unirradiated portion. Examples of the leaching solution may be ethanol, methanol, isopropyl alcohol, propanol, 2-methoxyethanol, acetonitrile, acetone, butanol, distilled water, or the combinations thereof.

Examples of a leaching method may be a spraying method, an ultrasonic cleaning method, a dipping method, or a bubble method. For example, the leaching is performed by dipping the substrate in 2-methoxyethanol for about 2 minutes.

Subsequently, a heat treatment is performed on the patterned oxide semiconductor thin film to provide required electrical, chemical, and/or physical properties. The heat treatment may remove remaining organics in the thin film and make the thin film dense and solid. For example, the heat treatment is performed on a hot plate at about 350° C. for about 3 hours. Since a boiling point of photosensitive benzoylacetone is about 260° C. and all benzoylacetone disappear by evaporation in the oxide semiconductor thin film when the present heat treatment process is over, hysteresis with respect to the electrical properties of the thin film will not remain. According to an embodiment of the inventive concepts, a separate heat treatment process to remove the photosensitive material will not be necessary. Also, since the heat treatment may be performed at a low temperature of about 350° C., it may be applied to a large-area glass substrate or a flexible substrate.

Thin Film Transistor Fabrication

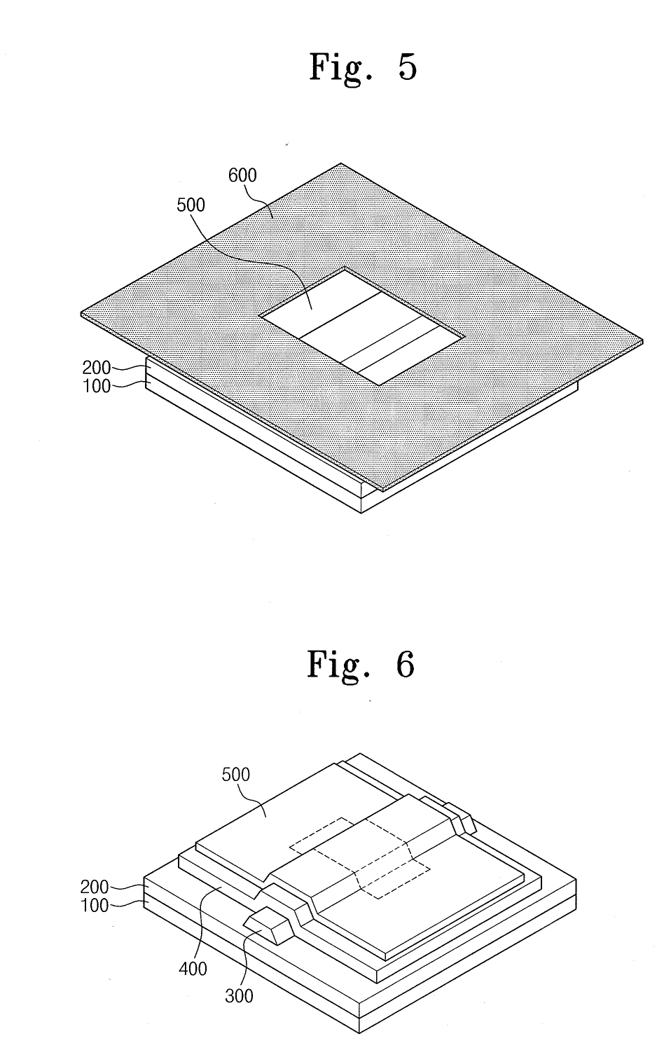

A thin film transistor was fabricated by using the foregoing oxide semiconductor thin film. For example, fabrication of a bottom gate thin film transistor in which a channel layer is formed on a gate is described with reference to FIGS. 3 through 8.

Referring to FIG. 3, a silicon oxide layer 200 is formed on a glass substrate 100 and a gate electrode 300 is formed by depositing about 2000 Å thick molybdenum tungsten (MoW) and performing photolithography. About 2000 Å thick silicon oxide is deposited by a chemical vapor deposition method to form a gate dielectric 400. In order to remove organics and impurities which may form on a surface, ultrasonic cleaning in the sequence of acetone, methanol, and deionized (DI)-water is performed for about 20 minutes, respectively. For uniform deposition during coating of a composition, ultrasonic cleaning was performed in a NaOH aqueous solution for about 10 minutes, and then cleaning is performed with deionized water several times.

Referring to FIG. 4, an IGZO thin film 500 is formed. Thin film coating is performed by a spin coating method and is performed in 5 steps such as at 500 rpm for 10 seconds, at 1500 rpm for 10 seconds, at 3000 rpm for 30 seconds, at 1500 rpm for 10 seconds, and at 500 rpm for 5 seconds. The oxide semiconductor thin film used as a channel layer is formed by removing a solvent through performing pre-bake on the coated substrate at a hot plate temperature of about 90° C. for about 2 minutes.

Referring to FIG. 5, a shadow mask 600, in which a portion where a pattern has to remain is opened, is positioned on the thin film 500, and then a light exposure is performed for about 15 minutes by using an aligner (UV radiation 365 nm, output 350 W, 25 mW/cm²) capable of irradiating ultraviolet having a 365 nm wavelength. The mask is removed carefully after completing the light exposure.

Referring to FIG. 6, in an ultraviolet-irradiated portion, a photosensitive material forms a strong bond with an oxide semiconductor precursor, for example, a chelating complex.

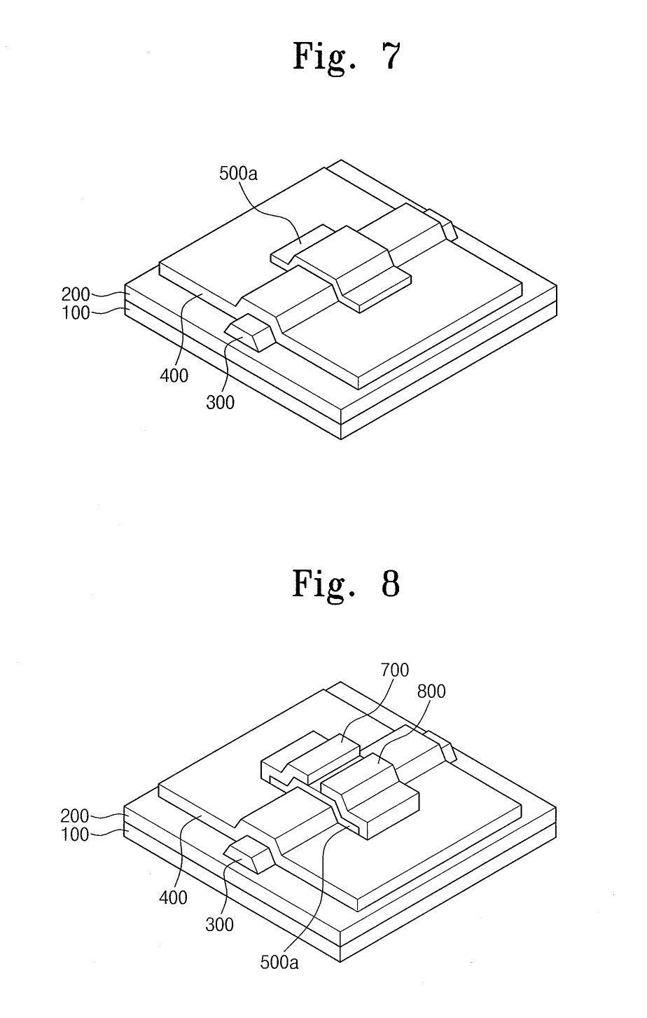

Referring to FIG. 7, leaching is performed for about 2 minutes by immediately dipping the ultraviolet-irradiated substrate in 2-methoxyethanol. The ultraviolet-irradiated portion remains and an ultraviolet-unirradiated portion is removed from the substrate. Subsequently, a patterned oxide semiconductor thin film 500a is formed by performing a heat treatment on a hot plate at about 350° C. for about 3 hours.

Referring to FIG. 8, in order to form a source-drain electrode, about 2000 Å thick aluminum electrode is deposited through a sputtering method by using a shadow mask capable of forming a pattern having a channel length of about 100 μm and a channel width of about 1000 μm. Polymethylmethacrylate ((C₅O₂H₈)n, PMMA) is formed by a spin coating method in order to improve the stability of a device and minimize the phenomenon with respect to a back channel. The spin coating is performed in 5 steps such as at 500 rpm for 10 seconds, at 1500 rpm for 10 seconds, at 3000 rpm for 30 seconds, at 1500 rpm for 10 seconds, and at 500 rpm for 5 seconds, and then a heat treatment was performed on a hot plate at about 150° C. for about 15 minutes.

### Evaluation

In order to form a comparative group with respect to the properties of an indium gallium zinc oxide thin film transistor using a photosensitive material containing oxide semiconductor composition according to an embodiment of the inventive concepts, a device having an unpatterned semiconductor layer and a device having a patterned semiconductor layer through a conventional photolithography process were fabricated at the same time.

The thin film transistor having an unpatterned semiconductor layer was fabricated by coating a solution-phase indium gallium zinc oxide without having a photosensitive material required for the pattern formation and heat treating. Light exposure and developing processes were not performed.

Meanwhile, in order to fabricate the thin film transistor having a patterned oxide semiconductor layer through a conventional photolithography process, a solution-phase indium gallium zinc oxide without having a photosensitive material was coated first. Thereafter, a heat treatment was performed and a negative photoresist (DNR300), which is one type of a photoresist, was coated by a spin-coating method. The spin coating was performed in 3 steps such as at 700 rpm for 15 seconds, at 2000 rpm for 15 seconds, and at 4000 rpm for 45 seconds, and then pre-bake was performed on a hot plate at about 110° C. for about 90 seconds. Next, light exposure was performed for about 12 seconds by using an aligner (UV radiation 365 nm, output 350 W, 25 mW/cm²) and the shadow mask used during the ultraviolet irradiation. Post-bake was performed on a hot plate at about 110° C. for about 90 seconds after the light exposure, and a photoresist pattern was formed by performing development for about 45 seconds using a photoresist developer MIF300 in order to remove a light-unexposed portion. An oxide semiconductor thin film pattern was formed by performing wet etching using the photoresist pattern as an etching mask for about 20 seconds with an etchant in which a buffered oxide etchant (BOE) and deionized water are mixed in a ratio of 1:20. The photoresist pattern was removed by using acetone. Thereafter, a source-drain was formed.

Tests on on/off ratios, field-effect mobilities, threshold voltages, subthreshold swing values, and reliabilities of the obtained thin film devices were performed through a current-voltage measurement instrument, and the device according to an embodiment of the inventive concepts and the device using a conventional photolithography process were compared to each other.

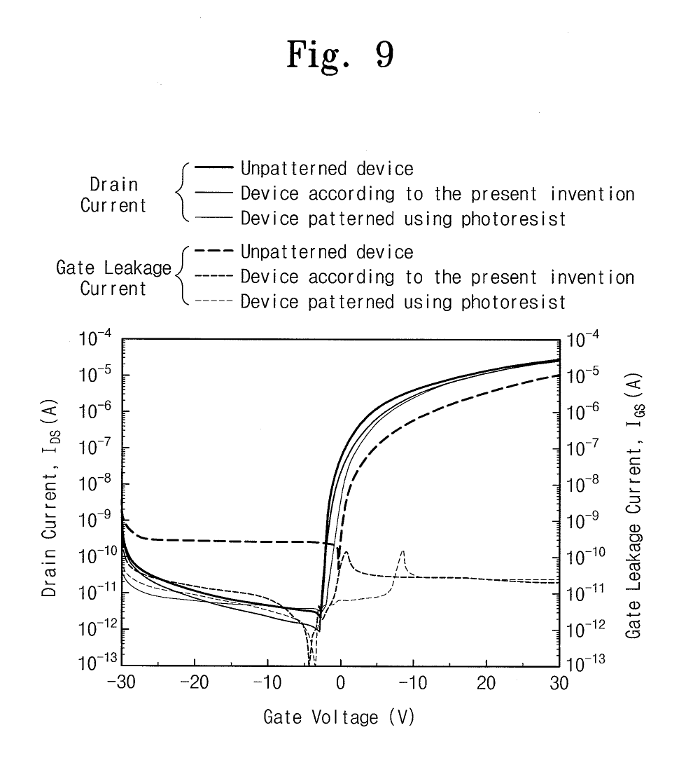

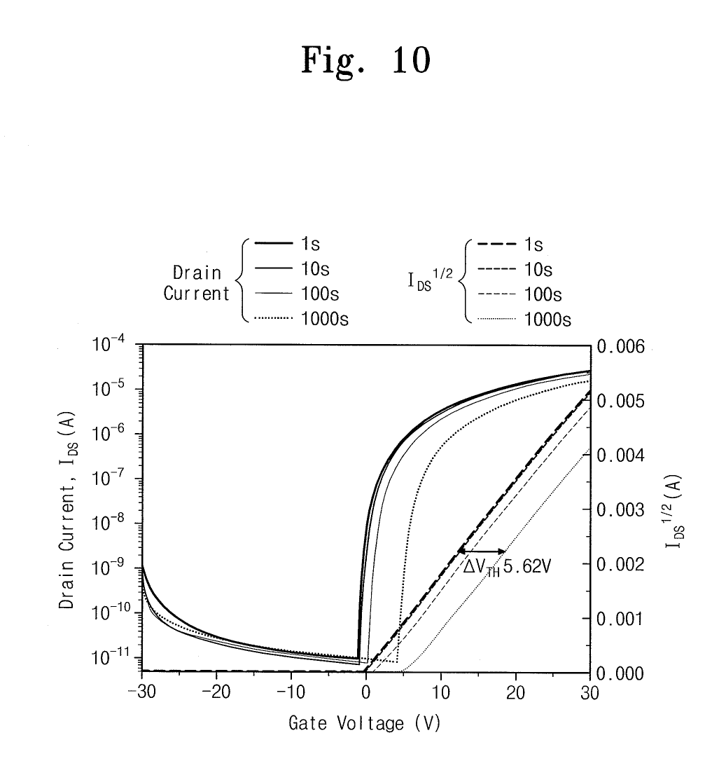

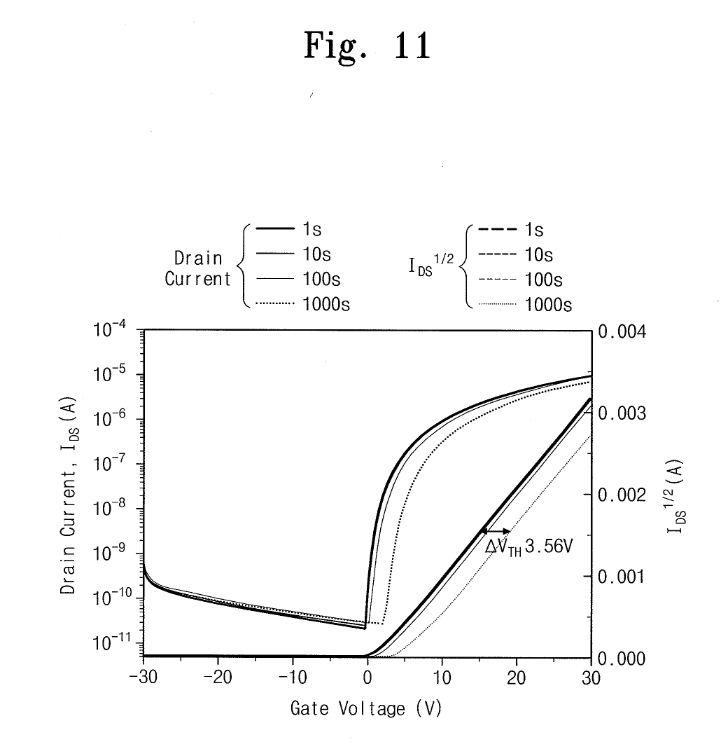

FIG. 9 is a graph showing electrical property changes of the indium-gallium-zinc oxide-based thin film transistor using the composition according to an embodiment of the inventive concepts, the unpatterned thin film transistor and the thin film transistor using a conventional photolithography process (using a photoresist). With respect to the unpatterned device, leakage current flowing between the source-gate is about 1.1×10⁻⁵ A at a gate voltage of about 30 V and it may be understood that very high leakage current flows in consideration of the fact that current between the source-drain is about 2.74×10⁻⁵ A. This may cause a limitation in that high power consumption is required for driving the device due to the high leakage current between the source and the gate. On the other hand, leakage current between the source-gate in the thin film transistor according to an embodiment of the inventive concepts is about 1.91×10⁻¹¹ A and leakage current between the source-gate in the thin film transistor using a conventional photolithography process is about 2.53×10⁻¹¹ A, which is very low values. Therefore, it is confirmed that the thin film transistor according to an embodiment of the inventive concepts may successively form a channel layer like the thin film transistor formed using a conventional lithography process.

The following Table 1 represents electrical properties of the device in FIG. 1.

TABLE 1

| | | | On/off | |
|---|---|---|---|---|
| | μ_{FE} | Vₜₕ | Ratio | S. S |
| Condition | (cm²/Vs) | (V) | (flicker rate) | (V/dec.) |
| Unpatterned device | 0.54 | −0.97 | 9.2 × 10⁶ | 0.53 |
| Self-patterned device | 0.63 | 1.11 | 3.1 × 10⁷ | 0.55 |
| according to an embodiment | | | | |
| of the inventive concepts | | | | |
| Patterned device using a | 0.77 | −0.68 | 5.6 × 10⁶ | 0.74 |
| photoresist | | | | |

Referring to Table 1, the field effect mobilities of thin film transistors in the unpatterned device, the device according to an embodiment of the inventive concepts, and the device using a conventional photolithography are about 0.54 cm²/Vs, about 0.63 cm²/Vs, and about 0.77 cm²/Vs, respectively. The on/off ratios are about 10⁶ or more and the subthreshold swing (S.S) values are also about 0.53V/dec., about 0.55 V/dec., and 0.74 V/dec., respectively. Therefore, excellent properties are obtained as a switching device. However, when each property is compared more closely, the subthreshold swing value of the device by a conventional photography process relatively deteriorated when compared to those of the unpatterned device and the device according to the present invention. It is considered that this is due to the damage of a back channel portion generated during the developing process of the photoresist used in the etching process and it is widely known that this affects electrical properties. Therefore, the device according to an embodiment of the inventive concepts has better properties, and low leakage current, a high on/off ratio, and high mobility is obtained in comparison to the device with the patterning process omitted (unpatterned device).

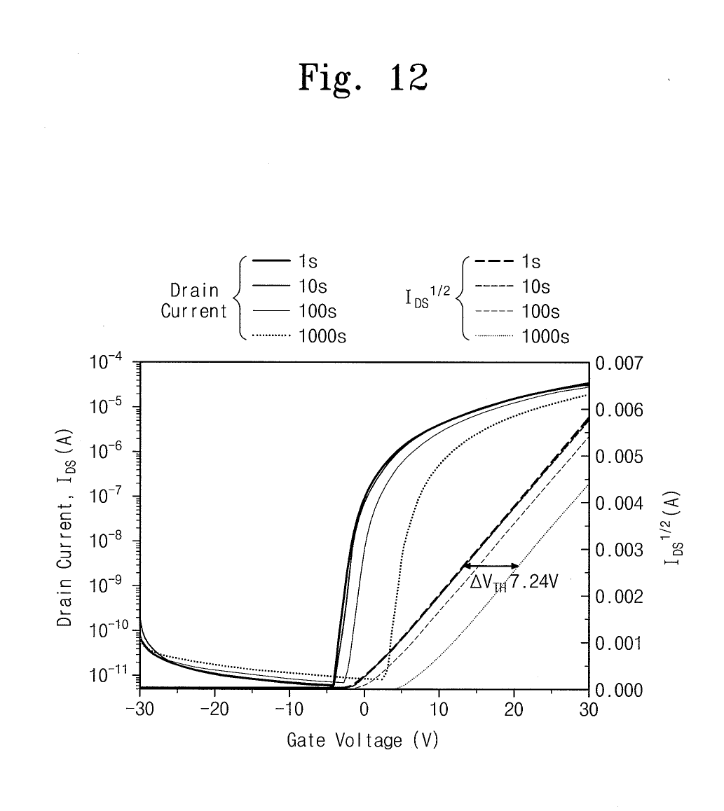

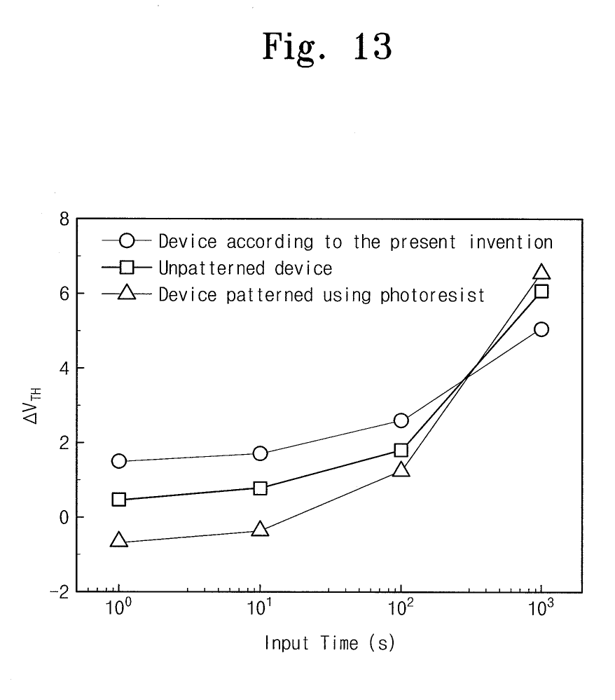

FIGS. 10 through 12 are graphs showing transfer characteristics with respect to positive bias stress (PBS) tests of thin film transistors according to each process. Threshold voltage values were measured under a stress test condition in which about 20 V of a gate bias voltage and about 10.1 V of a drain voltage were continuously applied for about 1 second, 10 seconds, 100 seconds, and 1000 seconds, and the measured threshold voltage values according to each condition were presented in FIG. 13.

The device with the patterning process omitted had a threshold voltage that moved about 5.62 V after the reliability test of 1000 seconds with respect to an initial measurement, the device according to an embodiment of the inventive concepts had a movement of about 3.56 V, and the device according to a conventional photolithography process had a movement of about 7.24 V. As a result, the device according to an embodiment of the inventive concepts had the best property in terms of the PBS test. The reason for this may be estimated below.

In the case of the device according to the conventional photolithography process, the back channel damage generated during the development of the photoresist causes device degradation, and accordingly, substhreshold swing characteristics deteriorate and characteristics are unstable in the reliability test.

However, in the case of the device according to an embodiment of the inventive concepts, the device in a gel state before the formation of the oxide thin film undergoes a leaching process in a selective curing state, and thereafter, a heat treatment condition of the solution-based indium-gallium-zinc oxide thin film at about 350° C., which is above a boiling point of benzoylacetone, will be obtained. Therefore, all the benzoylacetone that helped self-patterning will evaporate in the process of forming the oxide thin film and factors affecting the state changes during the leaching process and the process using ultraviolet or benzoylacetone will be disappear.

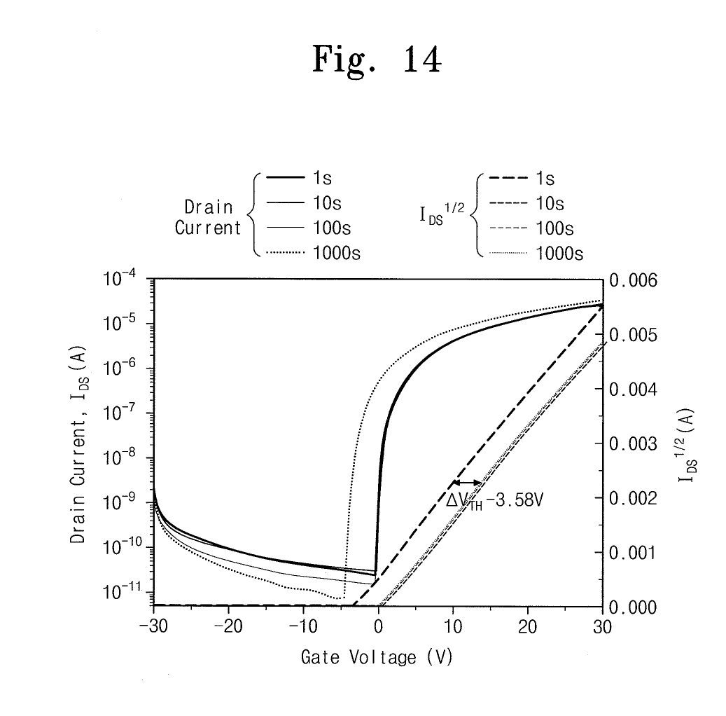

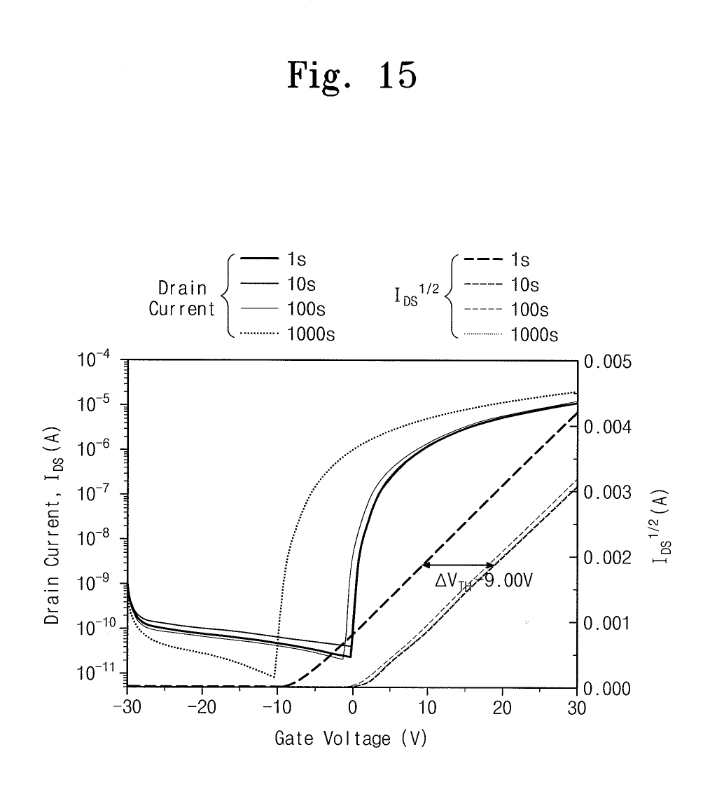

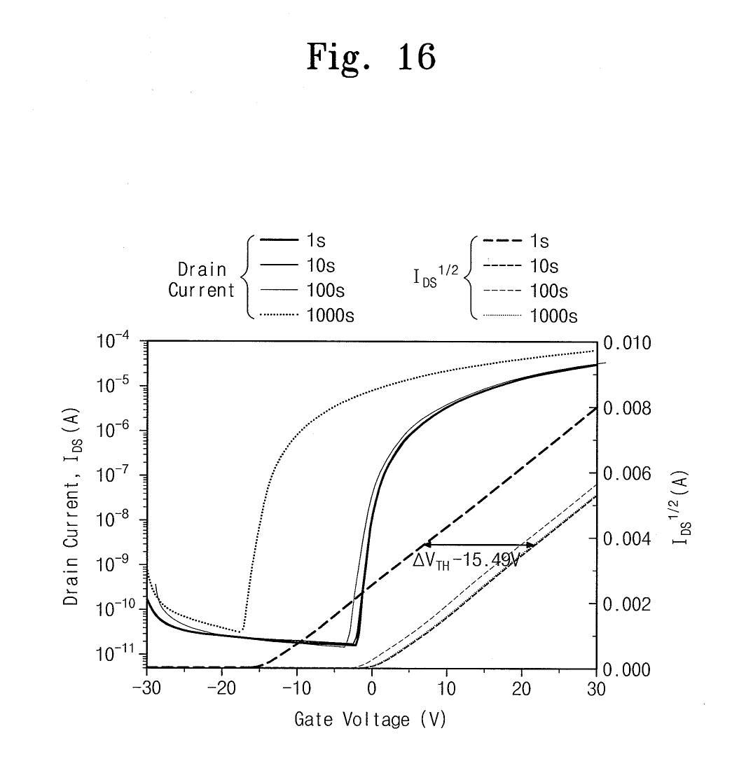

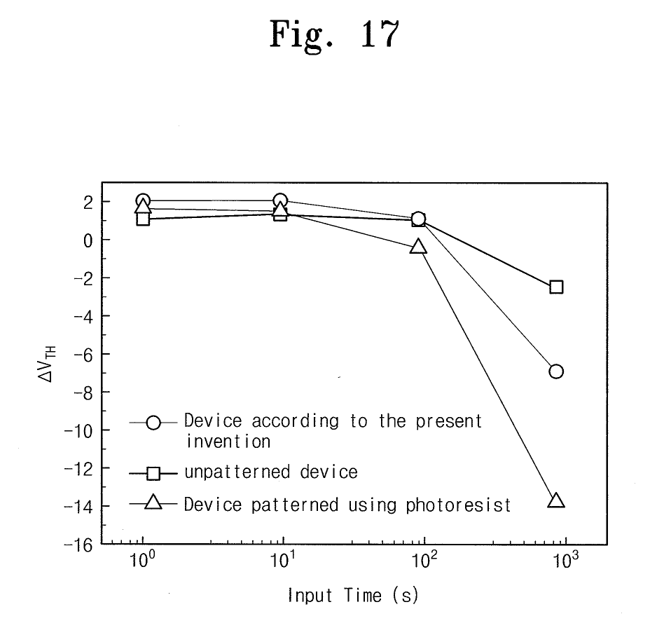

FIGS. 14 through 16 are graphs showing transfer characteristics with respect to negative bias stress (NBS) tests of thin film transistors according to each process. Threshold voltage values were measured under a stress test condition in which about −20 V of a gate bias voltage and about 10.1 V of a drain voltage were continuously applied for about 1 second, 10 seconds, 100 seconds, and 1000 seconds, and the measured threshold voltage values according to each condition were presented in FIG. 17. The unpatterned device had a threshold voltage that moved about −3.58 V after the reliability test of 1000 seconds with respect to an initial measurement, the device having a self-patterned channel according to an embodiment of the inventive concepts had a movement of about −9.00 V, and the device using a channel patterned by using a photoresist had a movement of about −15.49 V. The results of the NBS tests showed that the unpatterned device had the best property in terms of the NBS test. However, in the case of the device patterned by using a photoresist, the device had very poor characteristics in terms of reliability. The self-patterned device according to an embodiment of the inventive concepts had excellent characteristics in comparison to the device patterned by using a photoresist.

According to embodiments of the inventive concepts, since an oxide semiconductor may be selectively formed into a desired pattern at a low temperature of about 350° C. or less by using a liquid-phase photosensitive oxide semiconductor composition, electrical property degradation of a thin film using a typical photolithography process may be prevented and process steps may be simplified, and cost savings may be obtained because a photosensitive photoresist is not used.

According to embodiments of the inventive concepts, a highly reliable device having excellent electrical characteristics, such as low leakage current, high field-effect mobility, high flicker rate, and good on/off current characteristic, may be fabricated.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the inventive concepts is to be determined by the broadest permissible interpretation of the following claims and their equivalents, and shall not be restricted or limited by the foregoing detailed description.

What is claimed is:

1. An oxide semiconductor composition comprising:
an oxide semiconductor precursor; and
a photosensitive material.

2. The oxide semiconductor composition of claim 1, wherein the photosensitive material is included in a range of about 0.1 mol to about 1 mol with respect to 1 mol of the oxide semiconductor precursor.

3. The oxide semiconductor composition of claim 1, wherein light absorption of the photosensitive material is generated in an ultraviolet wavelength region of about 200 nm to about 450 nm.

4. The oxide semiconductor composition of claim 1, wherein the photosensitive material is selected from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

5. The oxide semiconductor composition of claim 4, wherein the oxide semiconductor precursor comprises a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.

6. The oxide semiconductor composition of claim 4, wherein the oxide semiconductor precursor comprises an indium compound, a zinc compound, and a gallium compound, and a molar ratio of the zinc compound to the indium compound is in a range of about 1:0.1 to about 0.1:1 and a molar ratio of the zinc compound to the gallium compound is in a range of about 1:0.1 to about 1:1.

7. A method of forming an oxide semiconductor thin film, the method comprising:
coating an oxide semiconductor composition including a photosensitive material and an oxide semiconductor precursor on a substrate to form an oxide semiconductor thin film;
patterning the oxide semiconductor thin film; and
heat treating the substrate in a temperature range of about 100° C.˜350° C.

8. The method of claim 7, wherein the patterning of the oxide semiconductor thin film comprises:
irradiating light to the oxide semiconductor thin film; and
removing the oxide semiconductor thin film that is not irradiated with light.

9. The method of claim 8, wherein the preparing of the photosensitive material comprises selecting the photosensitive material from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

10. The method of claim 7, wherein the removing of the oxide semiconductor thin film that is not irradiated with light comprises providing ethanol, methanol, isopropyl alcohol, propanol, 2-methoxyethanol, acetonitrile, acetone, butanol, distilled water, or a combination thereof as an etching solution to the oxide semiconductor thin film that is not irradiated with light.

11. The method of claim 10, wherein, during the heat treating, the photosensitive material is removed through evaporation and organics of the oxide semiconductor precursor are removed.

12. The method of claim 10, wherein the etching solution is provided by a spraying method, an ultrasonic cleaning method, a dipping method, or a bubble method.

13. The method of claim 7, wherein the coating of the oxide semiconductor composition on the substrate to form the oxide semiconductor thin film comprises coating the oxide semiconductor composition on a flexible substrate, a glass substrate, or a silicon substrate.

14. The method of claim 7, wherein the heat treating is performed with a furnace, a hot plate, or a rapid thermal process.

15. The method of claim 7, comprising performing a heat treatment to remove a solvent, before the removing of the oxide semiconductor thin film that is not irradiated with light.

16. An electronic device comprising:
an oxide semiconductor thin film formed by a method of claim 7;
a gate electrode spaced apart from and overlapping the oxide semiconductor thin film; and
source and drain electrodes electrically connected to the oxide semiconductor thin film and positioned at both sides of the gate electrode.

17. A semiconductor device comprising an oxide semiconductor thin film formed on a flexible substrate or a glass substrate,
wherein the oxide semiconductor thin film is formed by the method of claim 7.

18. A method of preparing an oxide semiconductor composition, the method comprising:
preparing an oxide semiconductor precursor solution;
preparing a photosensitive material solution; and
mixing the oxide semiconductor precursor solution and the photosensitive material solution.

19. The method of claim 18, wherein the preparing of the oxide semiconductor precursor solution comprises mixing a zinc compound and one or more compounds selected from the group consisting of an indium compound, a tin compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.

20. The method of claim 18, wherein the preparing of the photosensitive material solution comprises selecting the photosensitive material from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

21. An oxide thin film composition comprising:
a photosensitive material having a boiling point of about 400° C. or less and light absorption generated in an ultraviolet wavelength region of about 200 nm to about 450 nm; and
an oxide precursor.

22. The oxide thin film composition of claim 21, wherein the photosensitive material is selected from the group consisting of acetylacetone (C₅H₈O₂), benzoylacetone (C₁₀H₁₀O₂), benzoylacetoanilide (C₁₅H₁₃NO₂), 1-hydroxycyclohexyl phenyl ketone (C₁₃H₁₆O₂), phenylbis(2,4,6-trimethylbenzoyl)phosphine oxide (C₂₆H₂₇O₃P), 2-hydroxy-2-methyl-1-phenyl-1-propanone (C₁₀H₁₂O₂), and a combination thereof.

23. The oxide thin film composition of claim 21, wherein the oxide precursor comprises a zinc compound and one or more compounds selected from the group consisting of an indium compound, a tin, compound, a gallium compound, a hafnium compound, a magnesium compound, an aluminum compound, an yttrium compound, a tantalum compound, a titanium compound, a zirconium compound, a barium compound, a lanthanum compound, a manganese compound, a tungsten compound, a molybdenum compound, a cerium compound, a chromium compound, a scandium compound, a silicon compound, a neodymium compound, and a strontium compound.
